(19) United States
(12) Patent Application Publication
(10) Pub. No.: US 2025/0362097 A1
(43) Pub. Date: Nov. 27, 2025

(54) HEAT SPREADER, MANUFACTURING METHOD THEREOF, AND POROUS CARRIER THEREOF

(71) Applicant: CMTEK Co., Ltd., Hsinchu City (TW)

(72) Inventors: CHIN-JUI LIANG, Hsinchu City (TW); CHIN-PING LIN, Hsinchu City (TW)

(21) Appl. No.: 18/929,944

(22) Filed: Oct. 29, 2024

(30) Foreign Application Priority Data
May 22, 2024 (TW) 113118828
May 22, 2024 (TW) 113118855

(51) Int. Cl. F28F 21/02; F28F 21/04; F28F 21/08

(52) U.S. Cl. CPC F28F 21/02; F28F 21/04; F28F 21/089; F28F 21/084; F28F 21/085

(57) ABSTRACT

A heat spreader, a manufacturing method thereof, and a porous carrier thereof are provided. The porous carrier is composed of small-size particles, mid-size particles, and large-size particles. The small-size particles, the mid-size particles, and the large-size particles are each independently silicon carbide, diamond, diamond-like and/or graphene particles. A particle size ratio of the small-size particles, the mid-size particles, and the large-size particles is 1:2 to 2.5:3 to 20.

### CROSS-REFERENCE TO RELATED PATENT APPLICATION

This application claims the benefit of priority to Taiwan Patent Application No. 113118828, filed on May 22, 2024, and No. 113118855, filed on May 22, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a heat spreader, and more particularly to a heat spreader formed by loading a highly thermally conductive metal material onto a porous carrier made of a ceramic material and/or a hard carbon material, and a manufacturing method thereof.

### BACKGROUND OF THE DISCLOSURE

Electronic products are constantly being improved and updated. In order to meet the requirements of high integration, high transmission, high speed, and high efficiency, electronic products also require higher heat dissipation efficiency, in addition to basic functions. Commonly used cooling solutions, such as installing cooling fans or general metal heat sinks, are insufficient to cope with the cooling problems of servers and high-power products.

Silicon carbide has excellent characteristics such as high thermal conductivity, cold and hot shock resistance, acid and alkali resistance, lightness, and thinness. Silicon carbide-based heat spreaders have become one of the key components in the development of thermal management construction technology. However, the performance of such heat spreaders also depends on the microstructure of silicon carbide after molding, such as pore size, porosity, pore distribution, and pore connectivity. Yet, the conventional methods for manufacturing such heat spreaders generally have room for improvement in terms of process stability and product yield. For example, during the ceramic forming step, it is difficult to control the microstructure of the ceramic, resulting in poor process stability. As another example, during the impregnation step, the molten liquid containing metal cannot easily penetrate into the ceramic pores, resulting in a low yield of finished products.

### SUMMARY OF THE DISCLOSURE

In response to the above-referenced technical inadequacies, the present disclosure provides a porous carrier, which has high porosity, high rigidity, high thermal stability, and a low thermal expansion coefficient, and is thus suitable for carrying a highly thermally conductive metal material such as copper, silver, aluminum, or any alloy thereof, so as to meet the heat dissipation requirements of practical applications. On this basis, the present disclosure further provides a heat spreader and a manufacturing method thereof.

In order to solve the above-mentioned problems, one of the technical aspects adopted by the present disclosure is to provide a porous carrier for carrying a highly thermally conductive metal material. The porous carrier is composed of small-size particles, mid-size particles, and large-size particles. The small-size particles, the mid-size particles, and the large-size particles are each independently silicon carbide, diamond, diamond-like and/or graphene particles. A particle size ratio of the small-size particles, the mid-size particles, and the large-size particles is 1:2-2.5:3-20 (i.e., 1:2 to 2.5:3 to 20).

In order to solve the above-mentioned problems, another one of the technical aspects adopted by the present disclosure is to provide a heat spreader, which includes a porous carrier having the above-mentioned technical features and a metal surface layer. The metal surface layer is coated on an outside of the porous carrier, and is formed from a highly thermally conductive metal material. Furthermore, pores of the porous carrier are filled with the highly thermally conductive metal.

In order to solve the above-mentioned problems, yet another one of the technical aspects adopted by the present disclosure is to provide a manufacturing method of a heat spreader, which includes: providing a powder composition including small-size particles, mid-size particles, and large-size particles; performing a sintering treatment on the powder composition to form a porous carrier having a porosity from 20% to 70%; and performing an impregnation treatment with a metal melt on the porous carrier to form a heat spreader. The small-size particles, the mid-size particles, and the large-size particles are each independently silicon carbide, diamond, diamond-like and/or graphene particles, and a particle size ratio of the small-size particles, the mid-size particles, and the large-size particles is 1:2 to 2.5:3 to 20. The metal melt includes a highly thermally conductive metal. In the impregnation treatment, the highly thermally conductive metal is filled into pores of the porous carrier and loaded on an external surface of the porous carrier to form a metal surface layer.

In conclusion, the heat spreader and the porous carrier provided by the present disclosure, by virtue of the porous carrier being composed of small-size particles, mid-size particles, and large-size particles at a particle size ratio of 1:2 to 2.5:3 to 20, and the small-size particles, the mid-size particles, and the large-size particles each independently being silicon carbide, diamond, diamond-like and/or graphene particles, a highly thermally conductive metal material can be filled into pores of the porous carrier and exhibit good thermal conductivity by the bridging effect of ceramic material or hard carbon material particles that gather around each other, so as to meet high-power heat dissipation requirements.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view of a porous carrier of the present disclosure;

FIG. 2 is a schematic enlarged view of part II of FIG. 1;

FIG. 3 is a schematic view showing a process of loading a highly thermally conductive metal material onto the porous carrier of the present disclosure;

FIG. 4 is a schematic view of a heat spreader of the present disclosure;

FIG. 5 is a flow chart of a manufacturing method of the heat spreader according to an embodiment of the present disclosure;

FIG. 6 is a flow chart of a manufacturing method of the heat spreader according to another embodiment of the present disclosure;

FIG. 7 is a schematic view showing a plurality of porous carriers placed in an impregnation mold in a standing state and spaced apart from each other; and

FIG. 8 is a schematic view showing a plurality of heat spreaders formed by impregnation with a metal melt at the same time.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

Unless otherwise stated, the material(s) used in any described embodiment is/are commercially available material(s) or may be prepared by methods known in the art, and the method(s) or operation(s) used in any described embodiment is/are conventional method(s) or operation(s) generally known in the related art.

### First Embodiment

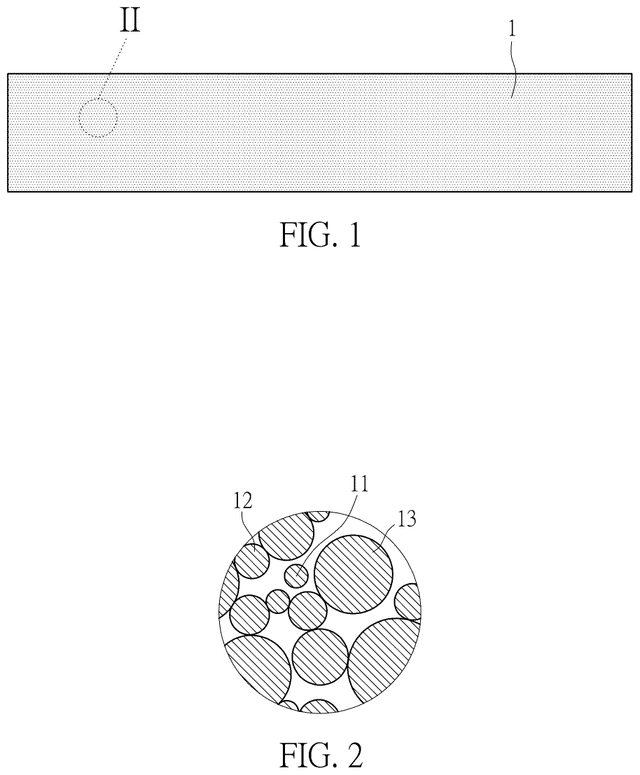

Referring to FIG. 1 and FIG. 2, a porous carrier 1 according to a first embodiment of the present disclosure is shown. As shown in FIG. 1 and FIG. 2, the porous carrier 1 of the present disclosure is composed of small-size particles 11, mid-size particles 12, and large-size particles 13. The small-size particles 11, the mid-size particles 12, and the large-size particles 13 are each independently ceramic material particles, hard carbon material particles, or a combination of the ceramic material particles and the hard carbon material particles. Therefore, the porous carrier 1 of the present disclosure can have high porosity, high rigidity, high thermal stability, and a low thermal expansion coefficient, and is thus suitable for carrying a highly thermally conductive metal material, so as to meet the heat dissipation requirements of practical applications. Specifically, the highly thermally conductive metal can be loaded on an external surface of the porous carrier 1 as well as implanted into the porous carrier 1, thereby reducing contact and diffusion thermal resistances.

Ceramic materials suitable for use in the present disclosure include, but are not limited to, silicon carbide, silicon dioxide, aluminum oxide, aluminum nitride, gallium nitride, and cubic boron nitride. Hard carbon materials suitable for use in the present disclosure include, but are not limited to, diamond, diamond-like carbon, and graphene. Highly thermally conductive metal materials suitable for use in the present disclosure include, but are not limited to, aluminum, copper, gold, silver, magnesium, titanium, nickel, and their alloys.

In the present embodiment, the small-size particles 11, the mid-size particles 12, and the large-size particles 13 are each independently silicon carbide, diamond, diamond-like and/or graphene particles. A particle size ratio of the small-size particles 11, the mid-size particles 12, and the large-size particles 13 is 1:2 to 2.5:3 to 20. It should be noted that the particle size of each of the small-size particles 11, the mid-size particles 12, and the large-size particles 13 can vary with the thickness of the porous carrier 1. Furthermore, the small-size particles 11, the mid-size particles 12, and the large-size particles 13 can be combined with each other by sintering to form the porous carrier 1. The porous carrier 1 can be formed into a block or sheet shape, but is not limited thereto. Preferably, a weight ratio of the small-size particles 11, the mid-size particles 12, and the large-size particles 13 is 1:3:4, based on a total weight of the porous carrier 1.

In practice, the particle size of the small-size particles 11 ranges from 0.1 μm to 5 μm, the particle size of the mid-size particles 12 ranges from 2 μm to 10 μm, and the particle size of the large-size particles 13 ranges from 10 μm to 100 μm. The porous carrier 1 has a porosity from 20% to 70%, i.e., a pore volume in the porous carrier 1 accounts for 20% to 70% of a total volume of the porous carrier 1. However, the above description is for exemplary purposes only, and is not meant to limit the scope of the present disclosure.

In certain embodiments, the porous carrier 1 of the present disclosure adopts a silicon carbide formulation, in which the silicon carbide particles accounts for at least 99% of the sum of the small-size particles 11, the mid-size particles 12, and the large-size particles 13. Therefore, the porous carrier 1 can have an improvement in thermal conductivity coefficient.

In certain embodiments, the porous carrier 1 of the present disclosure adopts a blend formulation of silicon carbide with diamond, in which the silicon carbide particles accounts for less than 30% of the sum of the small-size particles 11, the mid-size particles 12, and the large-size particles 13. Therefore, the porous carrier 1 can have an improvement in formability.

In certain embodiments, the porous carrier 1 of the present disclosure adopts a high purity graphene formulation, in which the silicon carbide particles accounts for less than 1% of the sum of the small-size particles 11, the mid-size particles 12, and the large-size particles 13. Therefore, the porous carrier 1 can also have an improvement in thermal conductivity coefficient.

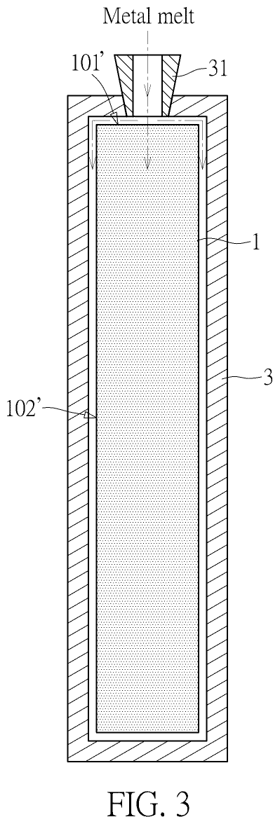

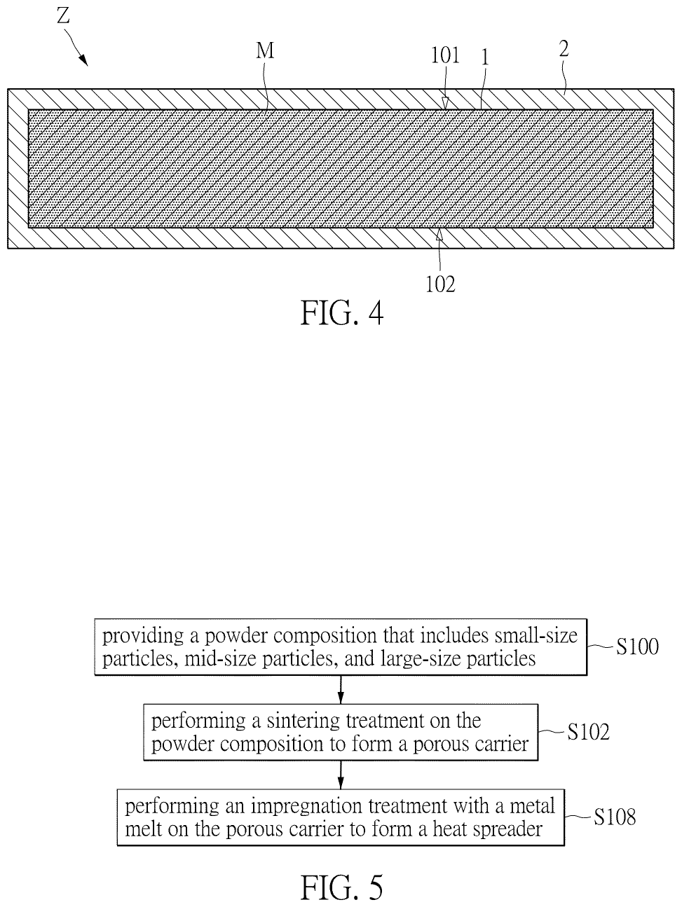

Reference is made to FIG. 3 and FIG. 4. FIG. 3 shows a means for loading a highly thermally conductive metal material M onto the porous carrier 1. FIG. 4 shows a heat spreader Z formed by the means. As shown in FIG. 3 and FIG. 4, the heat spreader Z according to an embodiment of the present disclosure includes the porous carrier 1 having the above-mentioned technical features and a metal surface layer 2 coated on an outside of the porous carrier 1.

In the embodiment of the present disclosure, the metal surface layer 2 is formed from the highly thermally conductive metal material M. Examples of the highly thermally conductive metal material M are as described above. In the process of forming the metal surface layer 2, the highly thermally conductive metal material M can penetrate into pores of the porous carrier 1. It is worth mentioning that the highly thermally conductive metal material M dispersed in the pores can exhibit good thermal conductivity by the bridging effect of ceramic material or hard carbon material particles that gather around each other.

In practice, the heat spreader Z of the present disclosure can have a thermal conductivity coefficient greater than 180 W/m·K, in which a thickness of the metal surface layer 2 is greater than 5 μm, and preferably ranges from 25 μm to 100 μm. However, the above description is for exemplary purposes only, and is not meant to limit the scope of the present disclosure.

As shown in FIG. 4, the porous carrier 1 has an upper surface 101 and a lower surface 102 opposite to the upper surface 101. The metal surface layer 2 and the heat spreader Z satisfy a relationship: 2 A/T≤50%; where A represents a covering thickness of the metal surface layer 2 on the upper surface 101 or the lower surface 102, and T represents a total thickness of the heat spreader Z.

### Second Embodiment

Referring to FIG. 5, a second embodiment of the present disclosure provides a manufacturing method of a heat spreader, which includes: step S100, providing a powder composition that includes small-size particles, mid-size particles, and large-size particles; step S102, performing a sintering treatment on the powder composition to form a porous carrier; and step S108, performing an impregnation treatment with a metal melt on the porous carrier to form a heat spreader.

Referring to FIG. 1 to FIG. 4, each step of the manufacturing method will be described in detail below.

In step S100, the small-size particles 11, the mid-size particles 12, and the large-size particles 13 are each independently ceramic material particles, hard carbon material particles, or the combination thereof. A particle size of the mid-size particles 12 is 2 times to 2.5 times a particle size of the small-size particles 11, and a particle size of the large-size particles 13 is 3 times to 20 times the particle size of the small-size particles 11. Ceramic materials suitable for use in the present disclosure include, but are not limited to, silicon carbide, silicon dioxide, aluminum oxide, aluminum nitride, gallium nitride, and cubic boron nitride. Hard carbon materials suitable for use in the present disclosure include, but are not limited to, diamond, diamond-like carbon, and graphene. Preferably, the small-size particles 11, the mid-size particles 12, and the large-size particles 13 are each independently silicon carbide particles, diamond particles, diamond-like particles, graphene particles, or any combination thereof.

In one of the possible or preferred embodiments, the particle size of the small-size particles 11 ranges from 0.1 μm to 5 μm, the particle size of the mid-size particles 12 ranges from 2 μm to 10 μm, and the particle size of the large-size particles 13 ranges from 10 μm to 100 μm. The particle size of the small-size particles 11 is smaller than the particle size of the mid-size particles 12. The particle size of the mid-size particles 12 is smaller than the particle size of the large-size particles 13.

In practice, the powder composition provided by step S100 can further include a conformal binder (such as polyvinyl alcohol) to improve the formability of the porous carrier 1. Specifically, the small-size particles 11, the mid-size particles 12, and the large-size particles 13 can be mixed with the conformal binder to form the powder composition. An amount of the conformal binder can be from 5 wt % to 20 wt %, relative to 100 wt % of the powder composition. If necessary, silicon carbide (SiC) can be used in place of the binder.

In step S102, the powder composition can be made into a blank having a fixed or semi-fixed shape by powder injection molding or powder press molding. Then, the sintering treatment is performed on the blank to allow the small-size particles 11, the mid-size particles 12, and the large-size particles 13 to combine with each other, so as to form the porous carrier 1 that has a porosity from 20% to 70%. The porous carrier 1 can be formed into a block or sheet shape, but is not limited thereto. Specifically, the sintering treatment can be performed under a normal pressure (1 atm) or vacuum condition or other pressure environments at a sintering temperature from 800°° C. to 1500° C. Preferably, a weight ratio of the small-size particles 11, the mid-size particles 12, and the large-size particles 13 is 1:3:4, based on a total weight of the porous carrier 1. Therefore, the porous carrier 1 can have high porosity, high rigidity, high thermal stability, and a low thermal expansion coefficient, and is thus suitable for carrying a highly thermally conductive metal material, so as to meet the heat dissipation requirements of practical applications.

In practice, a cooling treatment can be performed after the sintering treatment is completed, i.e., the porous carrier 1 formed by sintering is cooled to below a predetermined temperature or room temperature.

In step S108, the porous carrier 1 is placed in an impregnation mold 3, and the metal melt containing the highly thermally conductive metal material M is injected into the impregnation mold 3 through a gate 31 located above the porous carrier 1. Then, the highly thermally conductive metal material M, under heating and specific pressure conditions, can penetrate into pores of the porous carrier 1 and be loaded on an external surface of the porous carrier 1 to form a metal surface layer. It should be noted that a heating temperature can vary depending on the highly thermally conductive metal material M being used. For example, the heating temperature can be set in the range from 600° C. to 1300° C. The highly thermally conductive metal material M can be at least one selected from copper or its alloys, silver or its alloys, aluminum or its alloys, and other metals or alloys with high thermal conductivity, and is preferably aluminum.

In practice, a demolding treatment can be performed after the impregnation treatment is completed, i.e., the heat spreader Z finished by the impregnation treatment is taken out from the impregnation mold 3.

In the conventional impregnation process, a sintered body is impregnated with a metal melt through a relatively large-area surface (e.g., a front surface). It should be noted that the porous carrier 1 formed by step S100 and step S102 has a sufficiently high porosity, so that it can be impregnated with a metal melt in a standing state, i.e., the metal melt can penetrate into the interior of the porous carrier 1 through a relatively small-area surface (e.g., a side surface). Therefore, not only can a metal surface layer having a desired thickness (such as a thickness greater than 5 μm) be formed, but a more uniform impregnation effect of the metal melt can be achieved.

More specifically, the porous carrier 1 is formed into a block shape and has a relatively large-area surface 102′ and a relatively small-area surface 101′ connected to the relatively large-area surface 102′. An area of the relatively large-area surface 102′ is greater than an area of the relatively small-area surface 101′. In the impregnation treatment, the porous carrier 1 is in a standing state in the impregnation mold 3, so as to allow the metal melt containing the highly thermally conductive metal material M to come in direct contact with the relatively small-area surface 101′ through the gate 31.

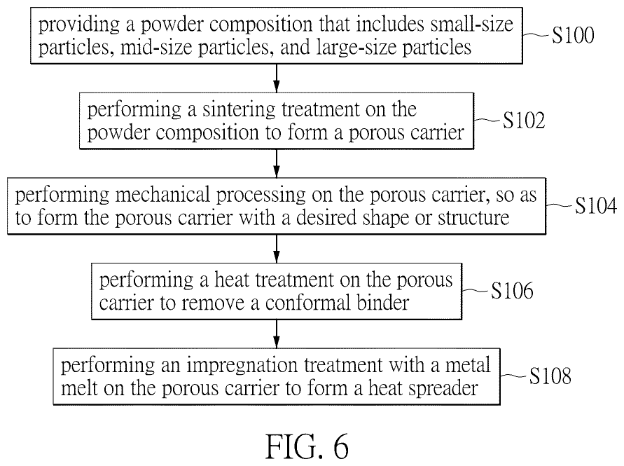

If necessary, as shown in FIG. 6, between the step of performing the sintering treatment (i.e., step S102) and the step of performing the impregnation treatment (i.e., step S108), the manufacturing method can further include a step of performing mechanical processing on the porous carrier 1 (i.e., step S104), so as to form the porous carrier 1 with a desired shape or structure. The mechanical processing suitable for use in the present disclosure can include cutting, grinding, drilling, or grooving the porous carrier 1, so that the porous carrier 1 has a shape or structure that matches the impregnation mold 3 or meets the requirements of subsequent applications such as circuit substrates.

Furthermore, when the powder composition includes a conformal binder, between the step of performing the sintering treatment (i.e., step S102) and the step of performing the impregnation treatment (i.e., step S108), the manufacturing method can further include a step of performing a heat treatment on the porous carrier 1 to remove the conformal binder (i.e., step S106).

The relevant technical details mentioned in the first embodiment are still valid in the present embodiment and will not be repeated here for the sake of brevity. Similarly, the technical details mentioned in the present embodiment can also be applied in the first embodiment.

### Third Embodiment

Referring to FIG. 5 and FIG. 6, a third embodiment of the present disclosure provides a manufacturing method of a heat spreader, which includes substantially the same steps as the manufacturing method of the second embodiment, i.e., main steps such as step S100, step S102, and step S108, and optional steps such as step S104 and step S108.

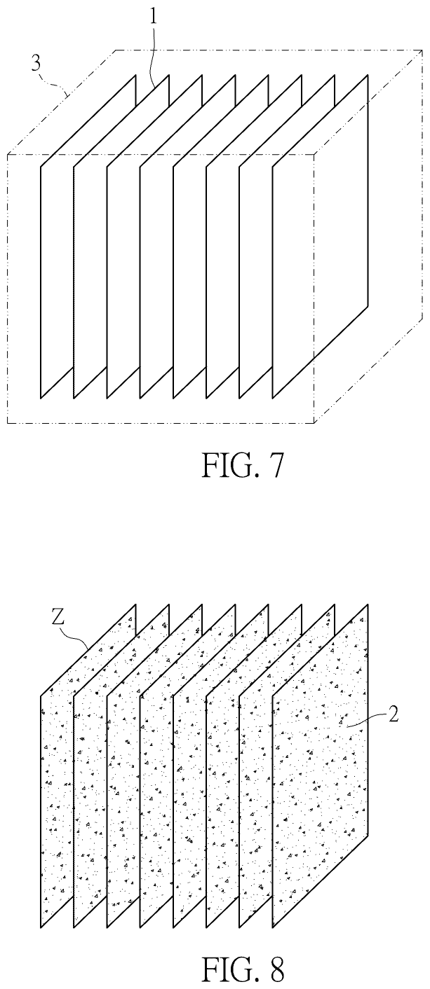

Reference is made to FIG. 7 and FIG. 8, the main difference between the present embodiment and the second embodiment is as follows: in step S108, two or more porous carriers are placed in an impregnation mold 3 in a standing state and spaced apart from each other, and the two or more porous carriers are all impregnated with a metal melt containing a highly thermally conductive metal material M at the same time. Therefore, a plurality of heat spreaders Z can be obtained after step S108 is completed.

### Beneficial Effects of the Embodiments

The heat spreader and the porous carrier provided by the present disclosure, by virtue of the porous carrier being composed of small-size particles, mid-size particles, and large-size particles at a particle size ratio of 1:2 to 2.5:3 to 20, and the small-size particles, the mid-size particles, and the large-size particles each independently being silicon carbide, diamond, diamond-like and/or graphene particles, a highly thermally conductive metal material can be filled into pores of the porous carrier and exhibit good thermal conductivity by the bridging effect of ceramic material or hard carbon material particles that gather around each other, so as to meet high-power heat dissipation requirements.

Furthermore, in the conventional impregnation process, a sintered body is impregnated with a metal melt through a relatively large-area surface (e.g., a front surface). The porous carrier provided by the present disclosure has a sufficiently high porosity, so that it can be impregnated with a metal melt in a standing state, i.e., the metal melt can penetrate into the interior of the porous carrier 1 through a relatively small-area surface (e.g., a side surface). Therefore, not only can a metal surface layer having a desired thickness (such as a thickness greater than 5 μm) be formed, but a more uniform impregnation effect of the metal melt can be achieved.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A porous carrier for carrying a highly thermally conductive metal material, composed of small-size particles, mid-size particles, and large-size particles that are each independently silicon carbide, diamond, diamond-like and/or graphene particles, wherein a particle size ratio of the small-size particles, the mid-size particles, and the large-size particles is 1:2 to 2.5:3 to 20.

2. The porous carrier according to claim 1, wherein the porous carrier has a porosity from 20% to 70%.

3. The porous carrier according to claim 1, wherein a particle size of the small-size particles ranges from 0.1 μm to 5 μm, a particle size of the mid-size particles ranges from 2 μm to 10 μm, and a particle size of the large-size particles ranges from 10 μm to 100 μm.

4. The porous carrier according to claim 1, wherein a weight ratio of the small-size particles, the mid-size particles, and the large-size particles is 1:3:4, based on a total weight of the porous carrier.

5. The porous carrier according to claim 1, wherein a percentage of the silicon carbide particles is greater than or equal to 99% out of a sum of the small-size particles, the mid-size particles, and the large-size particles.

6. The porous carrier according to claim 1, wherein a percentage of the silicon carbide particles is less than 30% out of a sum of the small-size particles, the mid-size particles, and the large-size particles.

7. The porous carrier according to claim 1, wherein a percentage of the silicon carbide particles is less than 1% out of a sum of the small-size particles, the mid-size particles, and the large-size particles.

8. A heat spreader, comprising:
the porous carrier as claimed in claim 1; and
a metal surface layer coated on an outside of the porous carrier and formed from a highly thermally conductive metal material, wherein pores of the porous carrier are filled with the highly thermally conductive metal.

9. The heat spreader according to claim 8, wherein the metal surface layer has a thickness greater than 5 μm.

10. The heat spreader according to claim 9, wherein the porous carrier has an upper surface and a lower surface opposite to the upper surface, and the metal surface layer and the heat spreader satisfy a relationship: 2A/T≤50%; where A represents a covering thickness of the metal surface layer on the upper surface or the lower surface, and T represents a total thickness of the heat spreader.

11. The heat spreader according to claim 8, wherein the highly thermally conductive metal is copper, silver, aluminum, or any alloy thereof; wherein the heat spreader has a thermal conductivity coefficient greater than 180 W/m·K.

12. A manufacturing method of a heat spreader, comprising:
providing a powder composition including small-size particles, mid-size particles, and large-size particles that are each independently silicon carbide, diamond, diamond-like and/or graphene particles, wherein a particle size ratio of the small-size particles, the mid-size particles, and the large-size particles is 1:2 to 2.5:3 to 20;
performing a sintering treatment on the powder composition to form a porous carrier, wherein a porosity of the porous carrier ranges from 20% to 70%; and
performing an impregnation treatment with a metal melt on the porous carrier to form a heat spreader, wherein the metal melt includes a highly thermally conductive metal, and in the impregnation treatment, the highly thermally conductive metal is filled into pores of the porous carrier and loaded on an external surface of the porous carrier to form a metal surface layer.

13. The manufacturing method according to claim 12, wherein the highly thermally conductive metal used in the impregnation treatment is copper, silver, aluminum, or any alloy thereof.

14. The manufacturing method according to claim 12, wherein the sintering treatment is performed under a normal atmospheric pressure, a vacuum, or a special atmosphere at a sintering temperature from 800° C. to 1500° C.

15. The manufacturing method according to claim 12, wherein, in the step of providing the powder composition, a particle size of the small-size particles ranges from 0.1 μm to 5 μm, a particle size of the mid-size particles ranges from 2 μm to 10 μm, and a particle size of the large-size particles ranges from 10 μm to 100 μm.

16. The manufacturing method according to claim 12, wherein, in the step of providing the powder composition, a weight ratio of the small-size particles, the mid-size particles, and the large-size particles is 1:3:4, based on a total weight of the porous carrier.

17. The manufacturing method according to claim 12, wherein, in the step of providing the powder composition, the small-size particles, the mid-size particles, and the large-size particles are mixed with a conformal binder to form the powder composition; wherein between the step of performing the sintering treatment and the step of performing the impregnation treatment, the manufacturing method further includes: performing a heat treatment on the porous carrier to remove the conformal binder.

18. The manufacturing method according to claim 12, wherein, between the step of performing the sintering treatment and the step of performing the impregnation treatment, the manufacturing method further includes: performing mechanical processing on the porous carrier, so as to form the porous carrier with a desired shape or structure.

19. The manufacturing method according to claim 12, wherein in the impregnation treatment, the porous carrier is placed in an impregnation mold, and the metal melt is injected into the impregnation mold through a gate located above the porous carrier.

20. The manufacturing method according to claim 12, wherein the porous carrier is formed into a block shape and has a relatively large-area surface and a relatively small-area surface connected to the relatively large-area surface, and an area of the relatively large-area surface is greater than an area of the relatively small-area surface; wherein in the impregnation treatment, the porous carrier is in a standing state in the impregnation mold, so as to allow the metal melt to come in direct contact with the relatively small-area surface through the gate.
